(19) United States
(12) Patent Application Publication
(10) Pub. No.: US 2024/0222425 A1
(43) Pub. Date: Jul. 4, 2024

(54) SEMICONDUCTOR STRUCTURE AND MANUFACTURING METHOD THEREOF

(71) Applicant: NANYA TECHNOLOGY CORPORATION, New Taipei City (TW)

(72) Inventor: Jhen-Yu TSAI, Kaohsiung City (TW)

(21) Appl. No.: 18/147,684

(22) Filed: Dec. 28, 2022

(51) Int. Cl. H01L 29/06; H01L 29/66; H01L 29/788

(52) U.S. Cl. CPC H01L 29/0642; H01L 29/66825; H01L 29/788

(57) ABSTRACT

A semiconductor structure includes a substrate, a first isolation layer and a source. The substrate has a body portion and a protruding portion extending from the body portion. The first isolation layer is located on the body portion of the substrate. The source is located on the first isolation layer. The source has a first portion and a second portion opposite to the first portion. The protruding portion of the substrate is located between the first portion and the second portion of the source.

### BACKGROUND

### Field of Invention

The present disclosure relates to a semiconductor structure and a manufacturing method of the semiconductor structure.

### Description of Related Art

In general, a leakage current may be generated by a floating body effect when transistors are operated. The current is generated by an impact ionization effect. The impact ionization effect may generate electron and hole pairs, and the electrons are withdrawn by the drain of the transistors. However, the holes are swept toward a floating body as transient storage for n-channel devices. The device performance of the transistors may be influenced by the holes.

### SUMMARY

An aspect of the present disclosure is related to a semiconductor structure.

According to an embodiment of the present disclosure, a semiconductor structure includes a substrate, a first isolation layer and a source. The substrate has a body portion and a protruding portion extending from the body portion. The first isolation layer is located on the body portion of the substrate. The source is located on the first isolation layer. The source has a first portion and a second portion opposite to the first portion. The protruding portion of the substrate is located between the first portion and the second portion of the source.

In one embodiment of the present disclosure, the first portion and the second portion of the source are symmetrically disposed along the protruding portion of the substrate.

In one embodiment of the present disclosure, a top surface of the protruding portion of the substrate is coplanar with a top surface of the source.

In one embodiment of the present disclosure, the top surface of the protruding portion, a sidewall of the protruding portion and a top surface of the body portion are formed a stepped structure.

In one embodiment of the present disclosure, a distance between the top surface of the protruding portion and a bottom surface of the substrate is greater than a distance between the top surface of the body portion and the bottom surface of the substrate.

In one embodiment of the present disclosure, a width of the protruding portion of the substrate is greater than a width of one of the first portion and the second portion of the source.

In one embodiment of the present disclosure, the semiconductor structure further includes a channel. The channel is located on the substrate. The width of the protruding portion of the substrate is less than a width of the channel.

In one embodiment of the present disclosure, the semiconductor structure further includes a drain. The drain is located on the channel. A thickness of the drain is substantially similar to a thickness of the channel.

In one embodiment of the present disclosure, the semiconductor structure further includes a second isolation layer. The second isolation layer is located in the substrate. The second isolation layer is in contact with a sidewall of the drain and a sidewall of the channel.

In one embodiment of the present disclosure, the semiconductor structure further includes a gate. The gate is located in the second isolation layer. A thickness of the gate is greater than the thickness of the channel.

Another aspect of the present disclosure is related to a manufacturing method of a semiconductor structure.

According to an embodiment of the present disclosure, a manufacturing method of a semiconductor structure includes: etching a substrate such that the substrate has a body portion and a protruding portion extending from the body portion; forming a first isolation layer on the substrate; forming a source on the first isolation layer; and etching the first isolation layer and the source such that a top surface of the protruding portion is exposed, wherein the source has a first portion and a second portion opposite to the first portion, and the protruding portion of the substrate is located between the first portion and the second portion of the source.

In one embodiment of the present disclosure, etching the first isolation layer and the source is performed such that the first portion and the second portion of the source are symmetrically disposed along the protruding portion of the substrate.

In one embodiment of the present disclosure, etching the first isolation layer and the source is performed such that the top surface of the protruding portion of the substrate is coplanar with a top surface of the source.

In one embodiment of the present disclosure, the method further includes forming a channel to cover the top surface of the protruding portion of the substrate and the top surface of the source.

In one embodiment of the present disclosure, the method further includes forming a drain on the channel such that a thickness of the drain is substantially similar to a thickness of the channel.

In one embodiment of the present disclosure, the method further includes: etching the drain, the channel, the source, the first isolation layer and the substrate to form a trench, wherein a sidewall of the drain and a sidewall of the channel are exposed; and forming a second isolation layer in the trench

In one embodiment of the present disclosure, the method further includes forming a gate on the second isolation layer and in the trench such that a thickness of the gate is greater than the thickness of the channel.

In the aforementioned embodiments of the present disclosure, the substrate of the semiconductor structure has the body portion and the protruding portion extending from the body portion, and the protruding portion of the substrate is located between the first portion and the second portion of the source, therefore a leakage current of the semiconductor structure due to the floating body effect may be reduced. To be more specific, when a voltage of the semiconductor structure is about 1 V, the semiconductor structure has a lower leakage current than conventional structures. Moreover, since the protruding portion of the substrate is located between the first portion and the second portion of the source and is in contact with the channel, a device performance of the semiconductor structure may be improved. That is, the body portion and the protruding portion of the substrate may be viewed as additional body contacts, and the additional body contacts may control holes generated by the floating body effect to be withdrawn to improve the leakage current of the semiconductor structure.

### BRIEF DESCRIPTION OF THE DRAWINGS

FIG. 1 illustrates a cross-sectional view of a semiconductor structure according to one embodiment of the present disclosure.

FIG. 2 illustrates a flow chart of a manufacturing method of a semiconductor structure according to one embodiment of the present disclosure.

FIG. 3 to FIG. 8 illustrate cross-sectional views at various steps of a manufacturing method of a semiconductor structure according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper,” “front,” “back” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

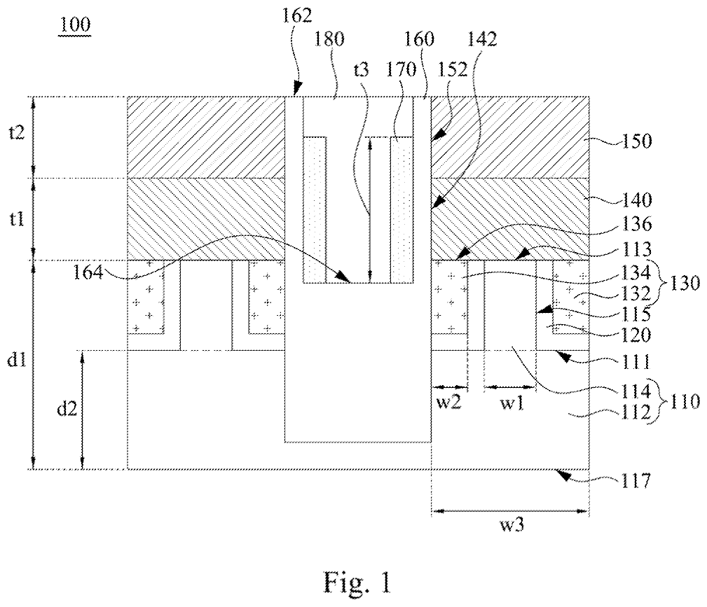

FIG. 1 illustrates a cross-sectional view of a semiconductor structure 100 according to one embodiment of the present disclosure. The semiconductor structure 100 includes a substrate 110, a first isolation layer 120 and a source 130. The substrate 110 of the semiconductor structure 100 has a body portion 112 and a protruding portion 114 extending from the body portion 112. For example, the substrate 110 of the semiconductor structure 100 may be made of a material that includes silicon, but it is not limited in this regard. The first isolation layer 120 of the semiconductor structure 100 is located on the body portion 112 of the substrate 110. To be more specific, the first isolation layer 120 of the semiconductor structure 100 covers a top surface 111 of the body portion 112 and a sidewall 115 of the protruding portion 114 of the substrate 110. That is, the first isolation layer 120 of the semiconductor structure 100 does not cover a top surface 113 of the protruding portion 114 of the substrate 110. The source 130 of the semiconductor structure 100 is located on the first isolation layer 120 of the semiconductor structure 100. It is to be noted that the source 130 of the semiconductor structure 100 has a first portion 132 and a second portion 134 opposite to the first portion 132. In addition, the protruding portion 114 of the substrate 110 of the semiconductor structure 100 is located between the first portion 132 and the second portion 134 of the source 130 of the semiconductor structure 100.

In some embodiments, the first portion 132 and the second portion 134 of the source 130 of the semiconductor structure 100 are symmetrically disposed along the protruding portion 114 of the substrate 110 of the semiconductor structure 100. Moreover, a distance d1 between the top surface 113 of the protruding portion 114 and a bottom surface 117 of the substrate 110 is greater than a distance d2 between the top surface 111 of the body portion 112 and the bottom surface 117 of the substrate 110. That is, the top surface 111 of the body portion 112 is located between the top surface 113 of the protruding portion 114 and the bottom surface 117 of the substrate 110. In some embodiments, the top surface 113 of the protruding portion 114, the sidewall 115 of the protruding portion 114 and the top surface 111 of the body portion 112 are formed a stepped structure.

Particularly, the substrate 110 of the semiconductor structure 100 has the body portion 112 and the protruding portion 114 extending from the body portion 112, and the protruding portion 114 of the substrate 110 of the semiconductor structure 100 is located between the first portion 132 and the second portion 134 of the source 130 of the semiconductor structure 100, therefore a leakage current of the semiconductor structure 100 due to the floating body effect may be reduced. To be more specific, when a voltage of the semiconductor structure 100 is about 1 V, the semiconductor structure 100 has a lower leakage current than conventional structures. Moreover, since the protruding portion 114 of the substrate 110 of the semiconductor structure 100 is located between the first portion 132 and the second portion 134 of the source 130 of the semiconductor structure 100 and is in contact with a channel 140, a device performance of the semiconductor structure 100 may be improved. That is, the body portion 112 and the protruding portion 114 of the substrate 110 of the semiconductor structure 100 may be viewed as additional body contacts, and the additional body contacts may control holes generated by the floating body effect to be withdrawn to improve the leakage current of the semiconductor structure 100.

In some embodiments, the top surface 113 of the protruding portion 114 of the substrate 110 of the semiconductor structure 100 is coplanar with a top surface 136 of the source 130 of the semiconductor structure 100. Moreover, the top surface 113 of the protruding portion 114 of the substrate 110 of the semiconductor structure 100 and the top surface 136 of the source 130 of the semiconductor structure 100 are coplanar with an edge of the first isolation layer 120 of the semiconductor structure 100.

In some embodiments, a width w1 of the protruding portion 114 of the substrate 110 of the semiconductor structure 100 is greater than a width w2 of the first portion 132 or the second portion 134 of the source 130 of the semiconductor structure 100. The protruding portion 114 of the substrate 110 of the semiconductor structure 100 is located between the first portion 132 and the second portion 134 of the source 130 of the semiconductor structure 100, therefore a leakage current of the semiconductor structure 100 due to the floating body effect may be reduced.

In some embodiments, the semiconductor structure 100 further includes the channel 140. The channel 140 of the semiconductor structure 100 is located on the protruding portion 114 of the substrate 110 of the semiconductor structure 100. In addition, the width w1 of the protruding portion 114 of the substrate 110 of the semiconductor structure 100 is less than a width w3 of the channel 140 of the semiconductor structure 100. The protruding portion 114 of the substrate 110 of the semiconductor structure 100 is located between the first portion 132 and the second portion 134 of the source 130 of the semiconductor structure 100 and is in contact with the channel 140, so a device performance of the semiconductor structure 100 may be improved.

In some embodiments, the semiconductor structure 100 further includes a drain 150. The drain 150 of the semiconductor structure 100 is located on the channel 140 of the semiconductor structure 100. A thickness t2 of the drain 150 of the semiconductor structure 100 is substantially similar to a thickness t1 of the channel 140 of the semiconductor structure 100. In some embodiments, the semiconductor structure 100 further includes a second isolation layer 160. The second isolation layer 160 of the semiconductor structure 100 is located in the substrate 110 of the semiconductor structure 100. In addition, the second isolation layer 160 is in contact with a sidewall 152 of the drain 150 and a sidewall 142 of the channel 140 of the semiconductor structure 100. The body portion 112 and the protruding portion 114 of the substrate 110 of the semiconductor structure 100 may be viewed as additional body contacts, and the additional body contacts may control holes generated by the floating body effect to be withdrawn to improve the leakage current of the semiconductor structure 100.

In some embodiments, the semiconductor structure 100 further includes a gate 170. The gate 170 of the semiconductor structure 100 is located in the second isolation layer 160. To be more specific, the gate 170 of the semiconductor structure 100 is located between a first surface 162 of the second isolation layer 160 and a second surface 164 of the second isolation layer 160 of the semiconductor structure 100. Moreover, a thickness t3 of the gate 170 is greater than the thickness t1 of the channel 140 and the thickness t2 of the drain 150 of the semiconductor structure 100. In some embodiments, the semiconductor structure 100 further includes a third isolation layer 180. The third isolation layer 180 of the semiconductor structure 100 covers the gate 170 of the semiconductor structure 100.

In the following description, a manufacturing method of a semiconductor structure will be described. It is to be noted that the connection relationship of the aforementioned elements will not be repeated.

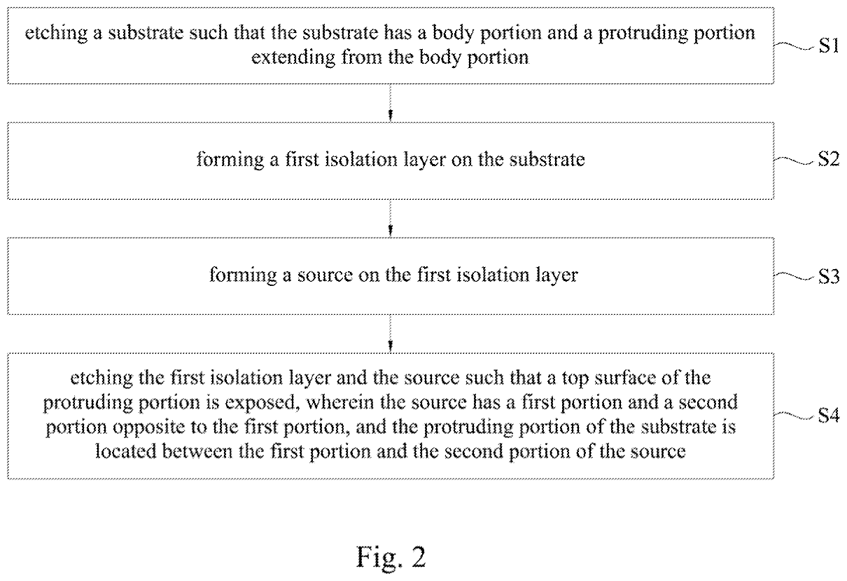

FIG. 2 illustrates a flow chart of a manufacturing method of a semiconductor structure according to one embodiment of the present disclosure. The manufacturing method of the semiconductor structure includes steps as outlined below. In step S1, a substrate is etched such that the substrate has a body portion and a protruding portion extending from the body portion. In step S2, a first isolation layer is formed on the substrate. In step S3, a source is formed on the first isolation layer. In step S4, the first isolation layer and the source are etched such that a top surface of the protruding portion is exposed, wherein the source has a first portion and a second portion opposite to the first portion, and the protruding portion of the substrate is located between the first portion and the second portion of the source. In the following description, the aforementioned steps will be described in detail.

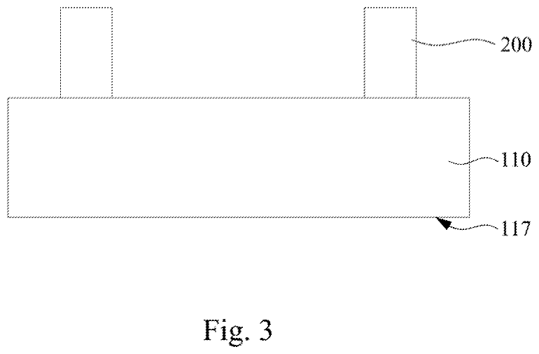

FIG. 3 to FIG. 8 illustrate cross-sectional views at various steps of a manufacturing method of a semiconductor structure according to one embodiment of the present disclosure. Referring to FIG. 3, a mask 200 may be disposed on the substrate 110. To be more specific, the mask 200 may be disposed on a surface opposite to the bottom surface 117 of the substrate 110. For example, the substrate 110 may be made of a material that includes silicon, but it is not limited in this regard. The mask 200 partially covers the substrate 110.

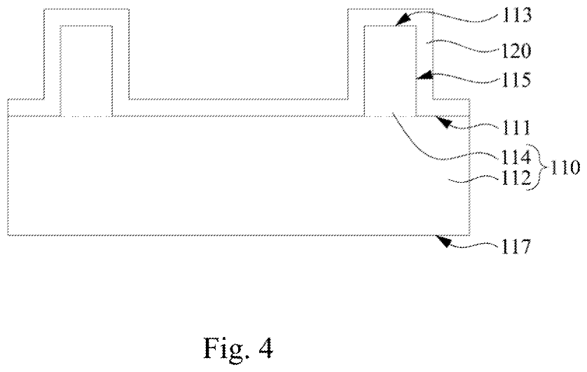

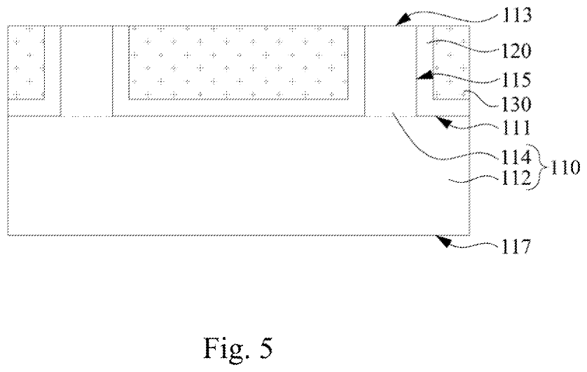

Referring to FIG. 4 and FIG. 5, after the mask 200 is disposed on the substrate 110, the substrate 110 may be etched such that the substrate 110 has the body portion 112 and the protruding portion 114 extending from the body portion 112. After the substrate 110 is etched, the mask 200 may be removed. Next, a first isolation layer 120 may be formed on the substrate 110. For example, the first isolation layer 120 may be formed by deposition such that the first isolation layer 120 is conformally located on the top surface 111 of the body portion 112, the top surface 113 of the protruding portion 114 and the sidewall 115 of the protruding portion 114. In some embodiments, the first isolation layer 120 may be made of a material that includes oxide, but it is not limited in this regard.

After the first isolation layer 120 is formed on the substrate 110, the source 130 may be formed on the first isolation layer 120. The source 130 may be made of a material that includes polysilicon, but it is not limited in this regard. After the source 130 is formed on the first isolation layer 120, the first isolation layer 120 and the source 130 may be etched such that the top surface 113 of the protruding portion 114 of the substrate 110 is exposed. For example, a chemical mechanical planarization (CMP) process may be performed to expose the top surface 113 of the protruding portion 114 of the substrate 110.

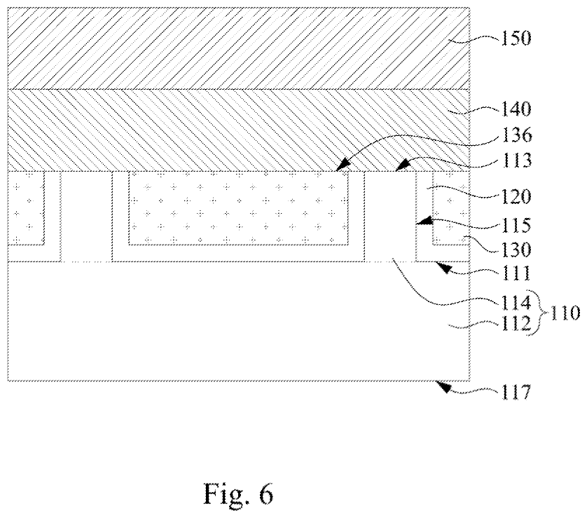

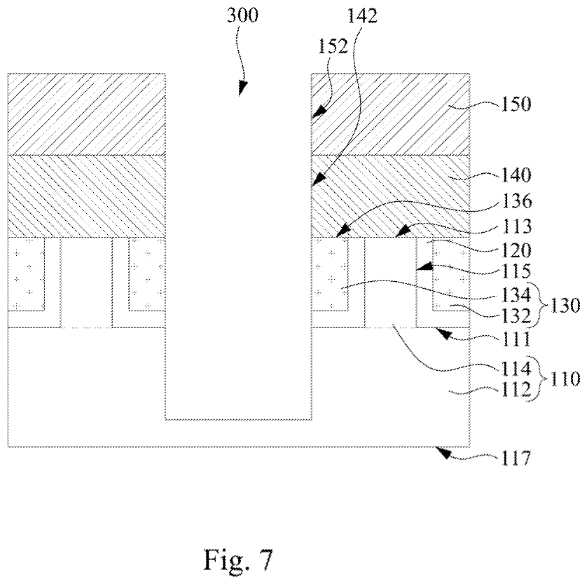

Referring to FIG. 6 and FIG. 7, after the top surface 113 of the protruding portion 114 of the substrate 110 is exposed, the channel 140 may be formed to cover the top surface 113 of the protruding portion 114 of the substrate 110 and the top surface 136 of the source 130. After the channel 140 is formed to cover the top surface 113 of the protruding portion 114 of the substrate 110 and the top surface 136 of the source 130, the drain 150 may be formed on the channel 140. For example, the channel 140 may be made of a material that includes light doped silicon, but it is not limited in this regard. The drain 150 may be made of a material that includes high doped silicon, but it is not limited in this regard. After the drain 150 is formed on the channel 140, the drain 150, the channel 140, the source 130, the first isolation layer 120 and the substrate 110 are etched to form a trench 300. The sidewall 152 of the drain 150 and the sidewall 142 of the channel 140 are exposed from the trench. In addition, the source 130 has the first portion 132 and the second portion 134 opposite to the first portion 132, and the protruding portion 114 of the substrate 110 is located between the first portion 132 and the second portion 134 of the source 130. In some embodiments, the top surface 113 of the protruding portion 114 of the substrate 110 is coplanar with the top surface 136 of the source 130.

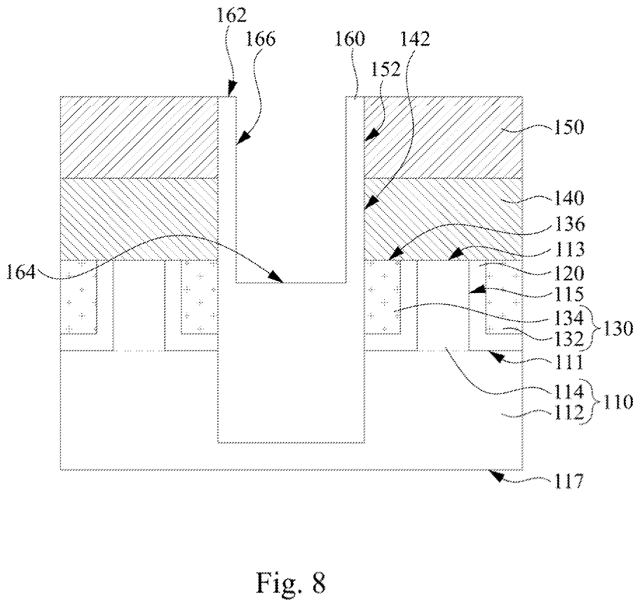

Referring to FIG. 8, after the sidewall 152 of the drain 150 and the sidewall 142 of the channel 140 are exposed from the trench, the second isolation layer 160 may be formed in the trench 300, and the second isolation layer 160 may be performed an etching process such that the second isolation layer 160 has a first surface 162, a second surface 164 and a sidewall 166. In addition, the first surface 162, the sidewall 166 and the second surface 164 of the second isolation layer 160 are formed a stepped structure. It is to be noted that the first portion 132 and the second portion 134 of the source 130 are symmetrically disposed along the protruding portion 114 of the substrate 110.

Referring back to FIG. 1, after the second isolation layer 160 is formed in the trench 300, the gate 170 may be formed on the second isolation layer 160 and in the trench 300 such that the thickness t3 of the gate 170 is greater than the thickness t1 of the channel 140 and the thickness t2 of the drain 150. After the gate 170 is formed, the third isolation layer 180 may be formed to cover the gate 170.

In summary, the substrate 110 of the semiconductor structure 100 has the body portion 112 and the protruding portion 114 extending from the body portion 112, and the protruding portion 114 of the substrate 110 of the semiconductor structure 100 is located between the first portion 132 and the second portion 134 of the source 130 of the semiconductor structure 100, therefore a leakage current of the semiconductor structure 100 due to the floating body effect may be reduced. To be more specific, when a voltage of the semiconductor structure 100 is about 1 V, the semiconductor structure 100 has a lower leakage current than conventional structures. Moreover, since the protruding portion 114 of the substrate 110 of the semiconductor structure 100 is located between the first portion 132 and the second portion 134 of the source 130 of the semiconductor structure 100 and is in contact with a channel 140, a device performance of the semiconductor structure 100 may be improved. That is, the body portion 112 and the protruding portion 114 of the substrate 110 of the semiconductor structure 100 may be viewed as additional body contacts, and the additional body contacts may control holes generated by the floating body effect to be withdrawn to improve the leakage current of the semiconductor structure 100.

Although the present disclosure has been described in considerable detail with reference to certain embodiments thereof, other embodiments are possible. Therefore, the spirit and scope of the appended claims should not be limited to the description of the embodiments contained herein. In view of the foregoing, it is intended that the present disclosure covers modifications and variations of this disclosure provided they fall within the scope of the following claims.

What is claimed is:

1. A semiconductor structure, comprising:
a substrate having a body portion and a protruding portion extending from the body portion;
a first isolation layer located on the body portion of the substrate; and
a source located on the first isolation layer and having a first portion and a second portion opposite to the first portion, wherein the protruding portion of the substrate is located between the first portion and the second portion of the source.

2. The semiconductor structure of claim 1, wherein the first portion and the second portion of the source are symmetrically disposed along the protruding portion of the substrate.

3. The semiconductor structure of claim 1, wherein a top surface of the protruding portion of the substrate is coplanar with a top surface of the source.

4. The semiconductor structure of claim 3, wherein the top surface of the protruding portion, a sidewall of the protruding portion and a top surface of the body portion are formed a stepped structure.

5. The semiconductor structure of claim 4, wherein a distance between the top surface of the protruding portion and a bottom surface of the substrate is greater than a distance between the top surface of the body portion and the bottom surface of the substrate.

6. The semiconductor structure of claim 1, wherein a width of the protruding portion of the substrate is greater than a width of one of the first portion and the second portion of the source.

7. The semiconductor structure of claim 6, further comprising:
a channel located on the substrate, wherein the width of the protruding portion of the substrate is less than a width of the channel.

8. The semiconductor structure of claim 7, further comprising:
a drain located on the channel, wherein a thickness of the drain is substantially similar to a thickness of the channel.

9. The semiconductor structure of claim 8, further comprising:
a second isolation layer located in the substrate, wherein the second isolation layer is in contact with a sidewall of the drain and a sidewall of the channel.

10. The semiconductor structure of claim 9, further comprising:
a gate located in the second isolation layer, wherein a thickness of the gate is greater than the thickness of the channel.

11. A manufacturing method of a semiconductor structure, comprising:
etching a substrate such that the substrate has a body portion and a protruding portion extending from the body portion;
forming a first isolation layer on the substrate;
forming a source on the first isolation layer; and
etching the first isolation layer and the source such that a top surface of the protruding portion is exposed, wherein the source has a first portion and a second portion opposite to the first portion, and the protruding portion of the substrate is located between the first portion and the second portion of the source.

12. The method of claim 11, wherein etching the first isolation layer and the source is performed such that the first portion and the second portion of the source are symmetrically disposed along the protruding portion of the substrate.

13. The method of claim 11, wherein etching the first isolation layer and the source is performed such that the top surface of the protruding portion of the substrate is coplanar with a top surface of the source.

14. The method of claim 13, further comprising:
forming a channel to cover the top surface of the protruding portion of the substrate and the top surface of the source.

15. The method of claim 14, further comprising:
forming a drain on the channel such that a thickness of the drain is substantially similar to a thickness of the channel.

16. The method of claim 15, further comprising:
etching the drain, the channel, the source, the first isolation layer and the substrate to form a trench, wherein a sidewall of the drain and a sidewall of the channel are exposed; and
forming a second isolation layer in the trench.

17. The method of claim 16, further comprising:
forming a gate on the second isolation layer and in the trench such that a thickness of the gate is greater than the thickness of the channel.
